(19) United States
(12) Patent Application Publication
(10) Pub. No.: US 2015/0054590 A1
(43) Pub. Date: Feb. 26, 2015

(54) OVEN CONTROLLED CRYSTAL OSCILLATOR

(71) Applicant: NIHON DEMPA KOGYO CO., LTD., TOKYO (JP)

(72) Inventor: FUMIO URABE, SAITAMA (JP)

(21) Appl. No.: 14/308,696

(22) Filed: Jun. 18, 2014

(30) Foreign Application Priority Data
Aug. 23, 2013 (JP) 2013-172975

(51) Int. Cl. H03L 1/02

(52) U.S. Cl. CPC H03L 1/02
USPC 331/70

(57) ABSTRACT

An oven controlled crystal oscillator (OCXO) is provided for improving temperature characteristics of a frequency. In the OCXO, a thermostatic oven 5 (20a) is provided in a thermostatic oven 9 (20b), a temperature control circuit 13 controls a temperature in the thermostatic oven 9 based on a temperature detected by a temperature sensing element 10, a first resonator 1 and a second resonator 2 are provided in the thermostatic oven 5, a temperature control circuit 8 controls the temperature based on an oscillation frequency difference between the two resonators, and especially, the temperature control circuit 13 controls the temperature to be within the temperature region where the oscillation frequency difference between the first resonator 1 and the second resonator 2 corresponds with the resonator temperature in a one-to-one manner, and the temperature gradient is either in a positive direction or in a negative direction.

### CROSS-REFERENCE TO RELATED APPLICATION

This application claims the priority benefit of Japan application serial no. 2013-172975, filed on Aug. 23, 2013. The entirety of the above-mentioned patent application is hereby incorporated by reference herein and made a part of this specification.

### TECHNICAL FIELD

This disclosure relates to an oven controlled crystal oscillator, especially to the oven controlled crystal oscillator capable of improving the temperature characteristics of frequency.

### DESCRIPTION OF THE RELATED ART

A conventional oven controlled crystal oscillator (OCXO) is a crystal oscillator which has a thermostatic oven that maintains a constant temperature and stores crystal resonators in the thermostatic oven to perform a stable oscillation that is resistant to influences of an ambient temperature.

Further, among the conventional OCXOs, there is a type of OCXO which oscillates two resonators having different frequencies and different temperature gradients to control a temperature in the thermostatic oven based on a difference between the different frequencies. The above-mentioned OCXO keeps the temperature in the thermostatic oven constant by using the fact that a variation of the frequency difference over the temperature is linear.

[Configuration of the Conventional OCXO: FIG. 4]

The conventional OCXO is explained by referring to FIG. 4. FIG. 4 shows a cross sectional view of the conventional OCXO. As shown in FIG. 4, the conventional OCXO has a first resonator 31 mounted on a front surface of a printed circuit board 34, a second resonator 32 mounted on a rear surface of the printed circuit board 34, and an oscillation circuit, a heater, a temperature control circuit, and the like equipped to the front surface and the rear surface of the printed circuit board 34.

The printed circuit board 34 is fixed to a base 33 by a plurality of lead terminals, and a case 35 is provided so as to cover the first resonator 31 and the second resonator 32, the printed circuit board 34, and the like. A thermostatic oven 30 is formed by the base 33 and the case 35, a frequency difference between the first resonator 31 and the second resonator 32 is detected by a frequency difference detecting unit, and the temperature control circuit controls the heater in accordance with the detected frequency difference to maintain a temperature in the thermostatic oven 30 constant.

[Circuit of the Conventional OCXO: FIG. 5]

Next, the conventional OCXO is explained by referring to FIG. 5. FIG. 5 shows a circuit diagram of the conventional OCXO. As shown in FIG. 5, in the conventional OCXO, an oscillation output from a first resonator 1 is inputted to an oscillation circuit 3 and an oscillation output terminal 14, and an oscillation output from a second resonator 2 is inputted to an oscillation circuit 4. AT-cut crystal resonators are employed for the first resonator 1 and the second resonator 2, and a variation of oscillation frequency of the first resonator 1 over the temperature and a variation of oscillation frequency of the second resonator 2 over the temperature are different. Further, the oscillation output terminal 14 outputs the oscillation output to the outside.

The oscillation circuits 3 and 4 amplify an inputted signal and output the amplified signal to an exclusive OR (ExOR) circuit 15. The ExOR circuit 15 takes an ExOR of the inputted signals and outputs the ExOR to a frequency difference detecting unit 6. The frequency difference detecting unit 6 detects a frequency difference from the ExOR obtained in the ExOR circuit 15 and outputs the frequency difference to a temperature control circuit 8. The temperature control circuit 8 controls a temperature in the thermostatic oven 30 by the heater and the like based on information of the frequency difference obtained from the frequency difference detecting unit 6.

[Characteristics of an AT-cut crystal resonator: FIG. 6]

The characteristics of the conventional OCXO in which the AT-cut crystal resonators are employed for the first resonator and the second resonator are explained by referring to FIG. 6. FIG. 6 shows a temperature characteristic diagram of the oscillation frequency difference between the first resonator and the second resonator when the AT-cut crystal resonators are employed for the first resonator and the second resonator. In FIG. 6, the horizontal axis shows a resonator temperature and the vertical axis shows a quantized frequency difference. As shown in FIG. 6, the frequency difference corresponds with the temperature of the resonator (resonator temperature) in a one-to-one manner when AT-cut crystal resonators are employed for the first resonator 1 and the second resonator 2, and the oven temperature can be controlled to an arbitrary temperature with the temperature control circuit.

[The Characteristics of an SC/IT-Cut Crystal Resonator: FIG. 7]

The characteristics of the conventional OCXO, in which (i) double-rotation cut crystal resonators, such as SC/IT-cut crystal resonators, are employed for the first resonator and the second resonator, and (ii) the first resonator is oscillated in a C-mode and the second resonator is oscillated in a B-mode, is explained by referring to FIG. 7. FIG. 7 shows a variation of oscillation frequency difference between the first resonator and the second resonator over the temperature.

Japanese Unexamined Patent Application Publication No. 2013-051676, “Crystal Oscillator” by Nihon Dempa Kogyo Co., Ltd. (Patent document 1); Japanese Unexamined Patent Application Publication No. H04-068903, “Oscillator having Temperature Sensing Function and Crystal Oscillator Element and Temperature Detection Method” by Asahi Denpa KK (Patent document 2); and Japanese Unexamined Patent Application Publication No. 2004-048686, “High Stability Piezoelectric Oscillator” by Toyo Communication Equipment Co., Ltd. (Patent document 3) each disclose related art.

Patent Document 1 discloses a crystal oscillator, in which an oscillation frequency difference between a first crystal oscillator and a second crystal oscillator is detected and the difference is supplied to a loop filter to control a heater in a thermostatic oven. The Patent Document 2 discloses an oscillator, in which a frequency difference between a fundamental oscillation and an n-th overtone oscillation is detected and a temperature in a thermostatic oven is controlled based on the difference. Patent Document 3 discloses a high-stability piezoelectric oscillator, in which a first thermostatic oven has a piezoelectric resonator therein, a second thermostatic oven has the first thermostatic oven therein, and the temperature in the first thermostatic oven is set lower than the temperature in the second thermostatic oven.

However, in the conventional OCXO, a combination of crystal resonators, whose variation of an oscillation frequency difference over the temperature is linear, is limited to AT-cut crystal resonators whose temperature gradient of a resonator frequency is minimized at different temperatures (temperatures of zero temperature coefficient (ZTC temperature)), and there was a problem that the variation of the frequency difference over the temperature change is not linear and that the temperature cannot be controlled when a double-rotation cut crystal resonator, such as an SC/IT-cut crystal resonator, that has a lower frequency variation rate relative to the ambient temperature than the AT-cut resonator, which means its frequency stability relative to the ambient temperature is high, is used.

In Patent Document 1, the first resonator and the second resonator employ crystal resonators whose characteristics of the frequency difference linearly correspond with the resonator temperature in a one-to-one manner, and the temperature characteristics of the frequency are not improved by using crystal resonators such as SC/IT-cut crystal resonators that have high frequency stability relative to the ambient temperature.

In Patent Document 1 and Patent Document 2, using a double thermostatic oven and controlling an operative temperature of resonators provided in an inner thermostatic oven by using an outer thermostatic oven are not disclosed. Further, in Patent Document 3, a double thermostatic oven is provided but it is for preventing electronic parts from deterioration due to aging by heat and not for stably controlling a temperature based on a frequency difference between two resonators.

The present disclosure is created in view of the aforementioned circumstances, and the present disclosure is to provide the OCXO which can employ the double-rotation cut resonators, such as SC/IT-cut crystal resonators, that have high frequency stability relative to the ambient temperature, and can improve the temperature characteristics of the frequency.

### SUMMARY

According to one of the aspects of the present disclosure, an oven controlled crystal oscillator, comprises: a first thermostatic oven; a second thermostatic oven provided in the first thermostatic oven; a temperature sensing element configured to detect a temperature in the first thermostatic oven; a first temperature control circuit configured to control the temperature in the first thermostatic oven based on the temperature detected by the temperature sensing element; a first resonator and a second resonator provided in the second thermostatic oven; a frequency difference detecting unit configured to detect an oscillation frequency difference between the first resonator and the second resonator; and a second temperature control circuit configured to control the temperature in the second thermostatic oven based on the detected frequency difference, wherein frequency characteristics of the first resonator and the second resonator over the temperature are different, and the first temperature control circuit controls the temperature to be within a temperature region where an oscillation frequency difference between the first resonator and the second resonator corresponds with a resonator temperature in a one-to-one manner. In this specification, “a temperature region where an oscillation frequency difference between the first resonator and the second resonator corresponds with a resonator temperature in a one-to-one manner” means that the oscillation frequency difference monotonically increases or decreases in accordance with changes of the resonator temperature. It is preferable that the ratio between the amount of a change of the resonator temperature and the amount of a change of the frequency difference is almost constant, and that the relationship between the resonator temperature and the frequency difference is linear.

### BRIEF DESCRIPTION OF THE DRAWINGS

FIG. 1 shows a cross sectional view of an OCXO according to a first exemplary embodiment of the present disclosure.

FIG. 2 shows a circuit diagram of the present oscillator.

FIG. 3 shows a diagram showing characteristics and a temperature range when an SC/IT-cut crystal resonator is employed for a first resonator and an AT-cut crystal resonator is employed for a second resonator.

FIG. 4 shows a cross sectional view of a conventional OCXO.

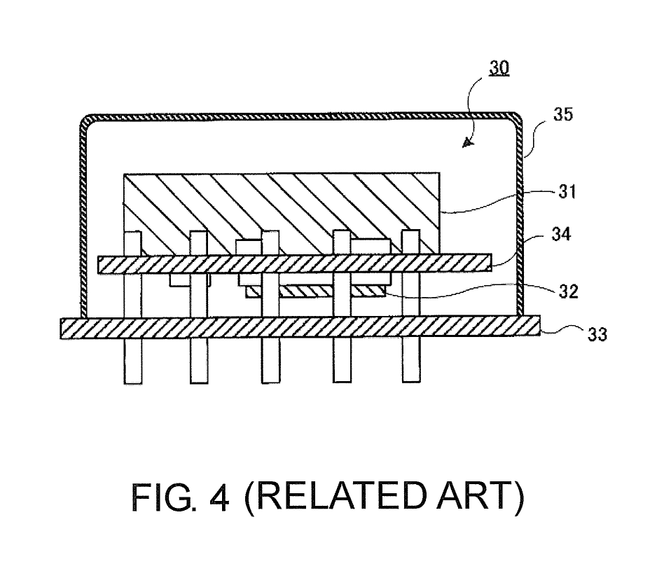

FIG. 5 shows a circuit diagram of the conventional OCXO.

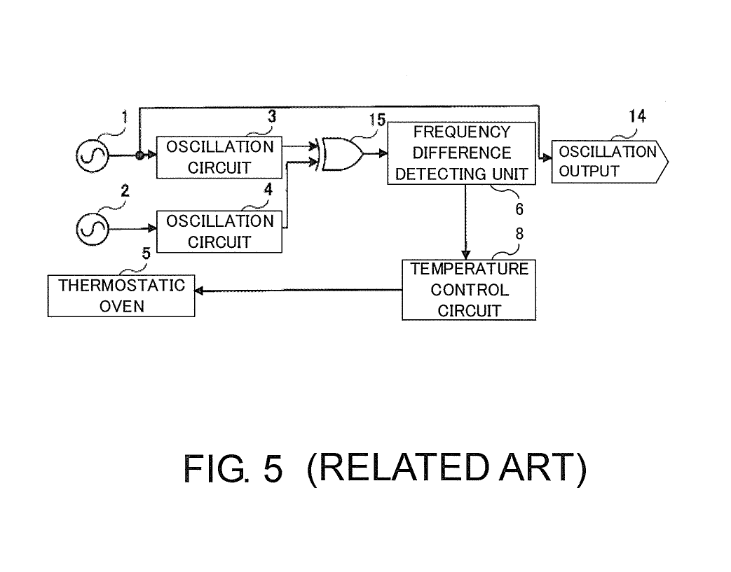

FIG. 6 shows a temperature characteristic diagram of an oscillation frequency difference between the first resonator and the second resonator when AT-cut crystal resonators are employed for the first resonator and the second resonator.

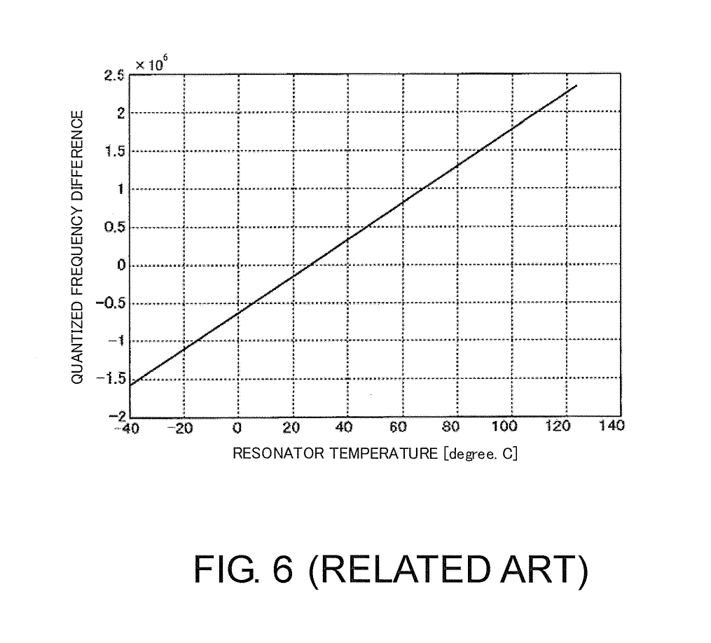

FIG. 7 shows a temperature characteristic diagram of the oscillation frequency difference between the first resonator and the second resonator when double-rotation cut resonators, such as SC/IT-cut crystal resonators, are employed for the first and the second resonators, and the first resonator is oscillated in a C-mode and the second resonator is oscillated in a B-mode.

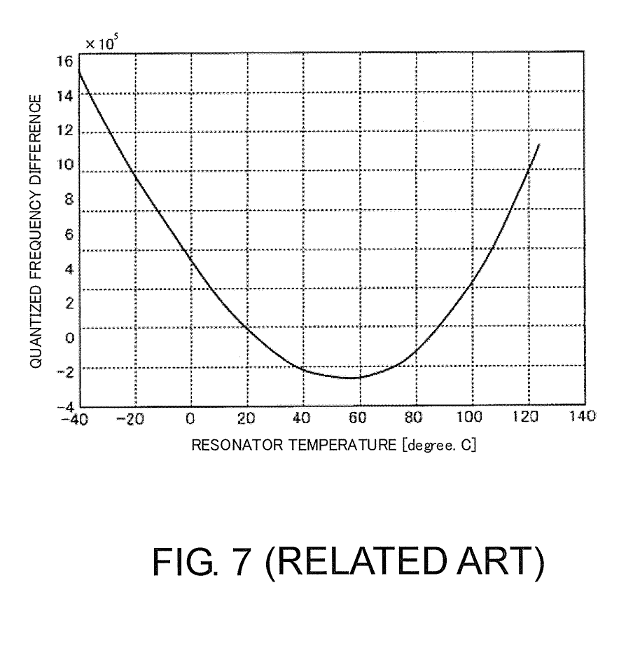

### DESCRIPTION OF EXEMPLARY EMBODIMENTS

The embodiment of the present disclosure is explained by referring to figures.

[Outline of Exemplary Embodiments]

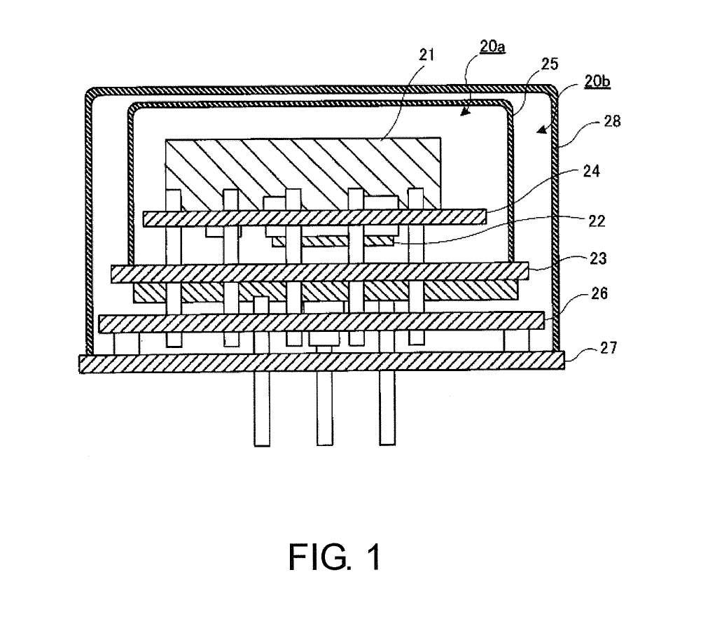

The OCXO according to the present embodiment of this disclosure has the second thermostatic oven in the first thermostatic oven, controls the temperature based on the temperature in the first thermostatic oven detected by the first temperature control circuit, has the first resonator and the second resonator in the second thermostatic oven, has the second temperature control circuit configured to control the temperature based on the oscillation frequency difference between the two resonators, and especially, the first temperature control circuit controls the temperature to be within the temperature region where the oscillation frequency difference between the first resonator and the second resonator corresponds with the resonator temperature in a one-to-one manner and the temperature gradient is either in a positive direction or in a negative direction. The OCXO can employ the double-rotation cut crystal resonators, such as SC/IT-cut crystal resonators with high frequency stability relative to the ambient temperature by limiting the operative temperature, and can improve the temperature characteristics of the frequency.

[Configuration of the Present Oscillator: FIG. 1]

The OCXO according to the present embodiment of this disclosure (present oscillator) is explained by referring to FIG. 1. FIG. 1 is a cross sectional view of the OCXO according to the present embodiment of the present disclosure. As shown in FIG. 1, the present oscillator has a first resonator 21 mounted on a front surface of a first printed circuit board 24, a second resonator 22 mounted on a rear surface of the printed circuit board 24, and an oscillation circuit, a heater, a temperature control circuit, and the like equipped to the front and rear surfaces of the first printed circuit board 24.

The first printed circuit board 24 is fixed to a first base 23 by a plurality of lead terminals, and a first case 25 is provided on the first base so as to cover the first resonator 21, the second resonator 22, the first printed circuit board 24, and the like. A thermostatic oven 20a is formed by the first base 23 and the first case 25.

Further, the first base 23 is fixed to a second printed circuit board 26 by a plurality of lead terminals, and the second printed circuit board 26 is fixed to a second base 27 by a plurality of lead terminals. A second case 28 is provided on the second base 27 so as to cover the first base 23, the first case 25, the second printed circuit board 26, and the like. A thermostatic oven 20b is formed by the second base 27 and the second case 28. In Claims, the thermostatic oven 20b is described as a “first thermostatic oven” and the thermostatic oven 20a is described as a “second thermostatic oven.”

A temperature in the thermostatic oven 20b is detected by a temperature sensing element such as a temperature sensor and the like provided in the thermostatic oven 20b, the first temperature control circuit (the first temperature control circuit in the Claims) controls the heater in the thermostatic oven 20b based on the detected temperature to maintain the temperature in the thermostatic oven 20b within a specific temperature region, and the inside of the thermostatic oven 20a operates within the specific temperature region. This specific temperature region will be explained later.

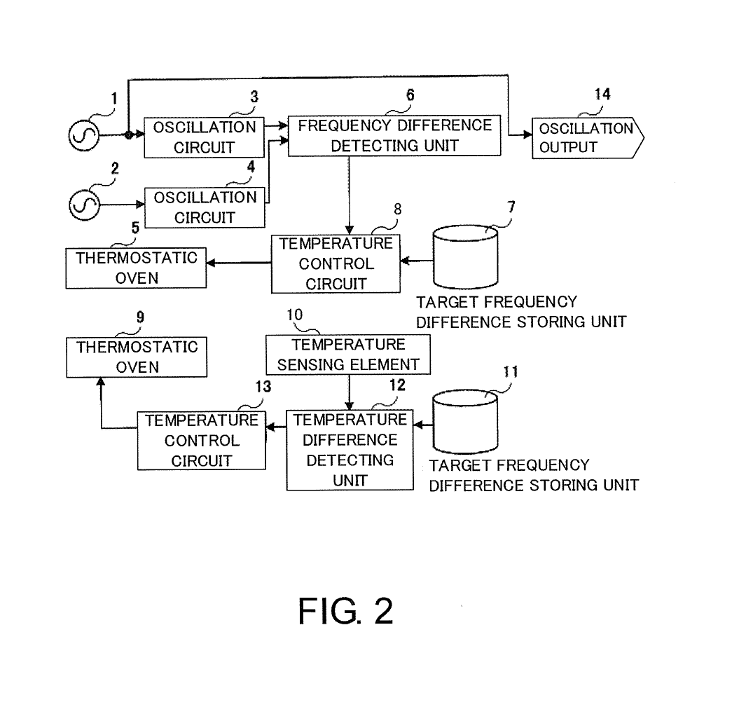

An oscillation frequency difference between the first resonator 21 and the second resonator 22 provided in the thermostatic oven 20a is detected by the frequency difference detecting unit, and the second temperature control circuit (the second temperature control circuit according to Claims) controls the heater in the thermostatic oven 20a according to the detected frequency difference to maintain the temperature in the thermostatic oven 20a constant.

[Circuit of the Present Oscillator: FIG. 2]

A circuit of the present oscillator is explained by referring to FIG. 2. FIG. 2 is a circuit diagram of the present oscillator. As shown in FIG. 2, in the present oscillator, an oscillation output from the first resonator 1 is inputted to the oscillation circuit 3 and the oscillation output terminal 14 and an oscillation output from the second resonator 2 is inputted to the oscillation circuit 4. Further, the oscillation output terminal 14 outputs the oscillation output to the outside. The first resonator 1 employs the double-rotation cut crystal resonator, such as the SC/IT-cut crystal resonator, and the second resonator 2 employs the AT-cut or the SC-cut B-mode crystal resonator, and the oscillation frequency of the first resonator over the temperature and the oscillation frequency of the second resonator over the temperature are different.

The SC/IT-cut crystal resonator is employed for the first resonator 1 because the frequency relative to the ambient temperature becomes more stable than when the AT-cut resonator is employed. Further, the AT-cut or SC-cut B-mode crystal resonator is employed for the second resonator 2 since the second resonator 2 is required only to operate as a temperature sensor.

The oscillator circuits 3 and 4 amplify an inputted signal and output the amplified signal to the frequency difference detecting unit 6. The frequency difference detecting unit 6 has an exclusive OR (ExOR) circuit on the input side and the ExOR circuit takes an ExOR of the inputted signal, detects a frequency difference from the ExOR, and outputs the frequency difference to the temperature control circuit 8. A target frequency difference storing unit 7 stores data of a target frequency difference. The temperature control circuit 8 reads the data of the target frequency difference from the target frequency difference storing unit 7 and controls a temperature in the thermostatic oven 5 by the heater and the like based on information of the frequency difference from the frequency difference detecting unit 6 and the data of the target frequency difference.

Specifically, the temperature control circuit 8 calculates a difference between the information of the frequency difference from the frequency difference detecting unit 6 and the data of the target frequency difference and controls the temperature in the thermostatic oven 5 to make the difference zero. The thermostatic oven 5 is the “second thermostatic oven” in Claims.

Further, a temperature sensing element 10, a target temperature storing unit 11, a temperature difference detecting unit 12, and a temperature control circuit 13 are mounted on a second printed circuit board 26 or the like. The temperature sensing element 10 is a temperature sensor that detects a temperature in a thermostatic oven 9 by using, for example, a thermistor. The target temperature storing unit 11 stores data of a target temperature to control the temperature in the thermostatic oven 9.

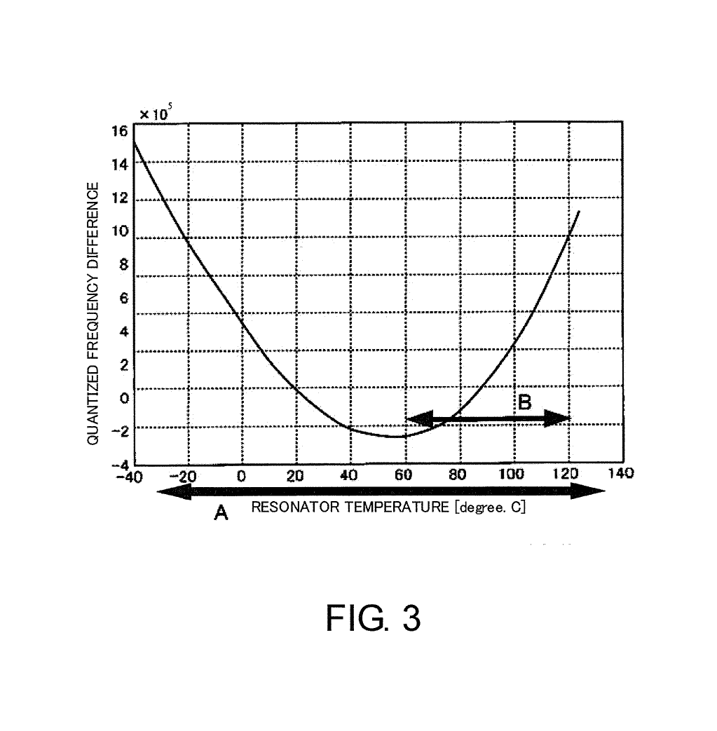

The temperature difference detecting unit 12 obtains a value of the temperature detected by the temperature sensing element 10, reads the data of the target temperature from the target temperature storing unit 11, detects a difference between the data of the target temperature and the value of the detected temperature, and outputs information of the temperature difference to the temperature control circuit 13. The temperature control circuit 13 controls the heater and the like to make the temperature difference zero based on the information of the temperature difference from the temperature difference detecting unit 12 to maintain the temperature in the thermostatic oven 9 within the specific temperature region. Therefore, the thermostatic oven 5 provided in the thermostatic oven 9 stably operates within the specific temperature region.

[Temperature Range of the Present Oscillator: FIG. 3]

A temperature range of the resonator temperature of the present oscillator is explained by referring to FIG. 3. FIG. 3 is a diagram showing characteristics and a temperature range when the SC/IT-cut crystal resonator is employed for the first resonator and the AT-cut crystal resonator is employed for the second resonator. In FIG. 3, the horizontal axis shows the resonator temperature and the vertical axis shows a quantized frequency difference. FIG. 3 shows the characteristics when the double-rotation cut crystal resonator, such as an SC/IT-cut crystal resonator, is employed for the first resonator and the AT-cut crystal resonator is employed for the second resonator. The frequency difference between the first resonator and the second resonator does not correspond with the resonator temperature in a one-to-one manner within a temperature range indicated by an arrow A, but the frequency difference between the first resonator and the second resonator corresponds with the resonator temperature in a one-to-one manner within a temperature region indicated by an arrow B, and the temperature can be controlled based on the frequency difference using the two resonators.

That is, by limiting the resonator temperature to be within the temperature range indicated by the arrow B, the frequency difference between the first resonator and the second resonator corresponds with the resonator temperature in a one-to-one manner, and the resonator temperature can be controlled to an arbitrary temperature by the temperature control circuit 8 of the OCXO. Thus, the temperature control circuit 13 sets the temperature in the thermostatic oven 9 to be equal to or higher than the lowest temperature where the frequency difference between the first resonator and the second resonator corresponds with the resonator temperature in a one-to-one manner, as shown by the arrow B in FIG. 3. That is, the temperature control circuit 13 sets the temperature in the thermostatic oven 9 to be within the temperature region where a temperature gradient is in a positive direction from around a point of inflection (the lowest temperature) in FIG. 3.

Further, the temperature can be controlled based on the frequency difference using the two resonators also by setting the temperature in thermostatic oven 9 to be within the temperature region where the temperature gradient is in a negative direction from around the point of inflection in FIG. 3, because the frequency difference corresponds with the resonator temperature in a one-to-one manner.

In the present oscillator, the thermostatic oven 5 (20a) is provided in the thermostatic oven 9 (20b), the temperature in the thermostatic oven 9 is controlled based on the temperature detected by the temperature control circuit 13 using the temperature sensing element 10, the first resonator 1 and the second resonator 2 are provided in the thermostatic oven 5, the temperature control circuit 8 controls the temperature based on the oscillation frequency difference between the two resonators, especially, the temperature control circuit 13 controls the temperature to be within the temperature region where (i) the oscillation frequency difference between the first resonator 1 and the second resonator 2 corresponds with the resonator temperature in a one-to-one manner and (ii) the temperature gradient is either in a positive direction or in a negative direction, and therefore the double-rotation cut crystal resonator, such as an SC/IT-cut crystal resonator, with high frequency stability relative to the ambient temperature can be employed by limiting the operation temperature, and the temperature characteristics of the frequency can be improved.

Especially, in the present oscillator, the temperature control circuit 13 controls the temperature to be within the temperature region where the temperature gradient is the positive direction from around the point of inflection, where the oscillation frequency difference between the first resonator 1 and the second resonator 2 is the lowest, and therefore, the double-rotation cut crystal resonator, such as an SC/IT-cut crystal resonator, can be employed and the temperature characteristics of the frequency can be improved.

The present disclosure is suitable for an oven controlled crystal oscillator in which the double-rotation cut crystal resonator, such as an SC/IT-cut crystal resonator, with high frequency stability relative to the ambient temperature can be employed, and can improve the temperature characteristics of the frequency.

What is claimed is:

1. An oven controlled crystal oscillator, comprising:
a first thermostatic oven;
a second thermostatic oven provided in the first thermostatic oven;
a temperature sensing element configured to detect a temperature in the first thermostatic oven;
a first temperature control circuit configured to control the temperature in the first thermostatic oven based on the temperature detected by the temperature sensing element;
a first resonator and a second resonator provided in the second thermostatic oven;
a frequency difference detecting unit configured to detect an oscillation frequency difference between the first resonator and the second resonator; and
a second temperature control circuit configured to control the temperature in the second thermostatic oven based on the detected frequency difference, wherein
frequency characteristics of the first resonator and the second resonator over the temperature are different, and
the first temperature control circuit controls the temperature to be within a temperature region where an oscillation frequency difference between the first resonator and the second resonator corresponds with a resonator temperature in a one-to-one manner.

2. The oven controlled crystal oscillator according to claim 1, wherein
the first resonator is a double-rotation cut crystal resonator, and
the first temperature control circuit is configured to control the temperature to be within the temperature region where the temperature gradient of a resonator temperature either in a positive direction or in a negative direction based on the oscillation frequency difference between the first resonator and the second resonator.

3. The oven controlled crystal oscillator according to claim 2, wherein
the first temperature control circuit is configured to control the temperature to be within the temperature region where the temperature gradient is in a positive direction from around the point of inflection where the oscillation frequency difference between the first resonator and the second resonator is the lowest.

4. The oven controlled crystal oscillator according to claim 1, wherein
the first resonator is an SC-cut or IT-cut crystal resonator.

5. The oven controlled crystal oscillator according to claim 1, wherein
the second resonator is an AT-cut or SC-cut B-mode crystal resonator.
